(19) United States
(12) Patent Application Publication
(10) Pub. No.: US 2016/0263627 A1
(43) Pub. Date: Sep. 15, 2016

(54) PROCESS FLUID CIRCULATION TYPE PROCESSING SYSTEM

(71) Applicant: DISCO CORPORATION, Tokyo (JP)

(72) Inventors: Masayoshi Uchida, Tokyo (JP); Miki Yoshida, Tokyo (JP); Satoshi Arai, Tokyo (JP)

(21) Appl. No.: 15/063,820

(22) Filed: Mar. 8, 2016

(30) Foreign Application Priority Data
Mar. 10, 2015 (JP) 2015-046664

(51) Int. Cl. B08B 3/08; H01L 21/687; B08B 3/14; H01L 21/67

(52) U.S. Cl. CPC B08B 3/08; H01L 21/6704; H01L 21/68771; H01L 21/67253; B08B 3/14

(57) ABSTRACT

A process fluid circulation type processing system has a processing apparatus that supplies a process fluid to a workpiece held on a chuck table. A process fluid supplying apparatus adds a surface active agent to pure water to produce the process fluid at a predetermined concentration and then supplies the process fluid to the processing apparatus. A pure water generating apparatus removes processing dust and impurities including the surface active agent from waste fluid discharged from the processing apparatus to thereby generate the pure water and then supplies the pure water to the process fluid supplying apparatus. The process fluid supplying apparatus includes a pure water passage, a pure water flow meter for measuring the flow rate of the pure water, and a surface active agent supplying unit for supplying the surface active agent to the pure water downstream of the pure water flow meter.

### BACKGROUND OF THE INVENTION

1. Field of the Invention

The present invention relates to a process fluid circulation type processing system.

2. Description of the Related Art

In a semiconductor fabrication process, a wafer as a workpiece is processed by a processing apparatus using a process fluid. Examples of the processing apparatus include a grinding apparatus for grinding a wafer as supplying a grinding fluid to thereby reduce the thickness of the wafer and a cutting apparatus for dividing a wafer into individual chips by using a cutting blade as supplying a cutting fluid. In the case of such a cutting apparatus, cutting dust is generated in cutting the workpiece. Accordingly, the cutting fluid is supplied to the workpiece in cutting, so as to prevent the adhesion of such cutting dust to the workpiece and also to remove the heat generated in cutting. Particularly in the case of cutting a semiconductor wafer, a pure water is used as the cutting fluid to minimize the adhesion of impurities to the semiconductor wafer.

However, in the case of producing an image sensor such as CCD and CMOS, the adhesion of fine cutting dust to the wafer causes a large problem. There is another problem such that corrosion occurs in electrode pads on each device in cutting a large-diameter wafer due to an increase in process time. To cope with these problems, there has been proposed a cutting method such that a predetermined concentration of additive is added to the pure water to produce a cutting fluid, which is used in cutting a wafer to thereby suppress the adhesion of cutting dust and also prevent the occurrence of corrosion (see Japanese Patent Laid-open No. 2006-150844, for example). Further, depending on the processing conditions in cutting, a large amount of pure water, for example, 2 to 15 liters per minute of pure water is used. Accordingly, there is another problem that a pure water producing cost is high. As measures against this problem, Japanese Patent No. 5086123 discloses a pure water generating apparatus for removing cutting dust from a pure water used as a cutting fluid to thereby allow the reuse of the cutting fluid with space-saving and low-cost equipment.

### SUMMARY OF THE INVENTION

However, the concentration of the additive is usually managed by adding a fixed amount of additive to a fixed amount of pure water flowing. Accordingly, in the case that the amount of the pure water to be used in the processing apparatus varies, the concentration of the additive is prone to vary. Particularly in the case that the concentration of the additive is very low (e.g., a concentration corresponding to a 10000-fold dilution factor), the variations in concentration of the additive easily become large. Accordingly, it is difficult to stably use a process fluid having a low concentration.

It is therefore an object of the present invention to provide a process fluid circulation type processing system which can feed a predetermined concentration of surface active agent to a pure water to be supplied to a processing apparatus even in the case that the flow rate of the pure water varies.

In accordance with an aspect of the present invention, there is provided a process fluid circulation type processing system including a processing apparatus for processing a workpiece held on a chuck table as supplying a process fluid to the workpiece, a process fluid supplying apparatus for adding a surface active agent to a pure water to thereby produce the process fluid at a predetermined concentration and then supplying the process fluid to the processing apparatus, and a pure water generating apparatus for removing processing dust and any impurities including the surface active agent from a waste fluid discharged from the processing apparatus to thereby generate the pure water and then supplying the pure water generated above to the process fluid supplying apparatus. The process fluid supplying apparatus includes a pure water passage for providing the flow of the pure water, a pure water flow meter for measuring the flow rate of the pure water flowing in the pure water passage, and surface active agent supplying means for supplying the surface active agent to the pure water flowing in the pure water passage at a position downstream of the pure water flow meter. The surface active agent supplying means supplies a predetermined amount of the surface active agent so that the concentration of the surface active agent with respect to the flow rate of the pure water becomes a predetermined concentration. The surface active agent supplied by the surface active agent supplying means is mixed with the pure water flowing in the pure water passage in the condition of a turbulent flow.

Preferably, the surface active agent supplying means supplies the predetermined amount of the surface active agent separately over plural times. Preferably, the process fluid supplying apparatus further includes a conductivity meter for measuring the conductivity of the process fluid flowing in the pure water passage after adding the surface active agent to the pure water, and control means connected to the conductivity meter for determining that the surface active agent has been added to the pure water when the conductivity measured by the conductivity meter is greater than a threshold value.

Preferably, the surface active agent supplying means includes a surface active agent source, a supply passage for connecting the surface active agent source to the pure water passage, a pump provided in the supply passage for feeding the surface active agent to the pure water passage, and a surface active agent flow meter provided in the supply passage for measuring the flow rate of the surface active agent flowing in the supply passage, the pump being controlled so that the flow rate of the surface active agent measured by the surface active agent flow meter becomes the predetermined amount with respect to the flow rate of the pure water measured by the pure water flow meter.

According to the process fluid circulation type processing system of the present invention, the process fluid can be circulated and reused to thereby suppress a pure water producing cost. Further, since the surface active agent is added to the pure water to produce the process fluid, it is possible to prevent the corrosion of the workpiece and the adhesion of cutting dust to the workpiece. The surface active agent supplying means of the process fluid supplying apparatus functions to add the surface active agent in a predetermined amount according to the flow rate of the pure water, so that the concentration of the surface active agent in the pure water can be easily made stable. Further, since the surface active agent is mixed with the pure water flowing in the pure water passage in the condition of a turbulent flow, any mixing tank or the like is not required to thereby improve the efficiency and contribute to space saving.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a process fluid circulation type processing system according to a preferred embodiment of the present invention;

FIG. 2 is an exploded perspective view of a pure water generating apparatus included in the processing system shown in FIG. 1;

FIG. 3 is a schematic block diagram of a process fluid supplying apparatus included in the processing system shown in FIG. 1; and

FIG. 4 is a graph showing the relation between the conductivity of a process fluid and the concentration of a surface active agent.

### DETAILED DESCRIPTION OF THE PREFERRED EMBODIMENT

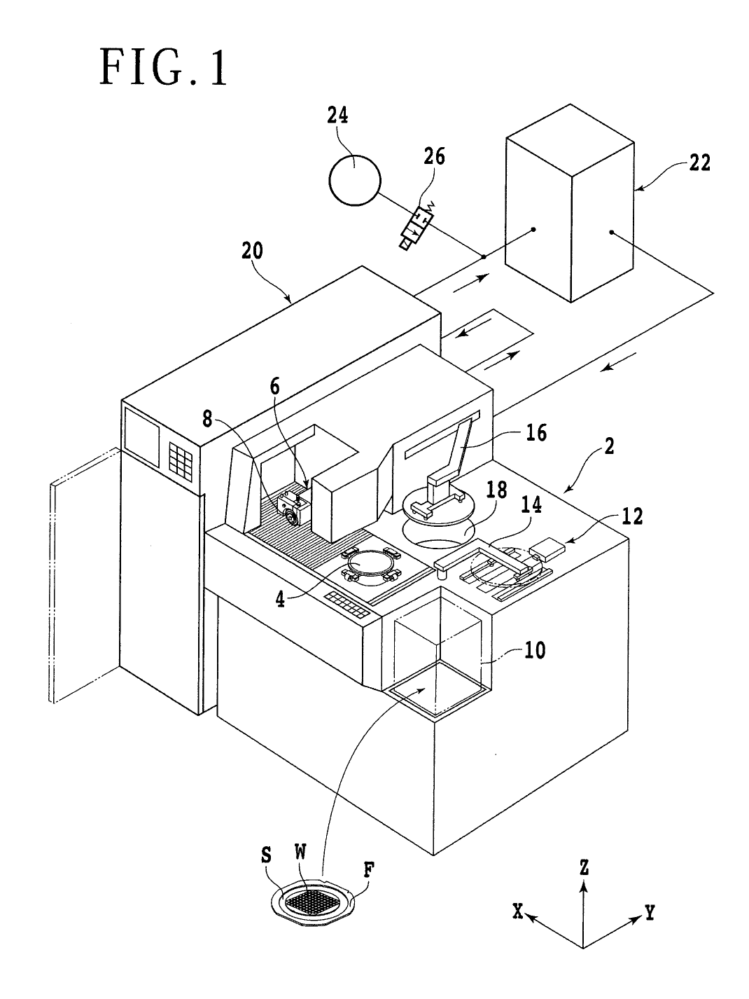

A preferred embodiment of the present invention will now be described in detail with reference to the drawings. Referring to FIG. 1, there is shown a perspective view of a process fluid circulation type processing system according to this preferred embodiment. The process fluid circulation type processing system includes a cutting apparatus 2 as a processing apparatus in this preferred embodiment. In the present invention, however, the processing apparatus is not limited to a cutting apparatus, but any other processing apparatuses such as a grinding apparatus may be adopted.

The cutting apparatus 2 includes a chuck table 4 for holding a wafer W and a cutting unit 6 having a cutting blade 8 for cutting the wafer W held on the chuck table 4. The wafer W is supported through an adhesive sheet S to an annular frame F in such a manner that the wafer W is attached to the central portion of the adhesive sheet S and the annular frame F is attached to the peripheral portion of the adhesive sheet S. The wafer W thus supported through the adhesive sheet S to the annular frame F is stored in a cassette 10. The cassette 10 is set at a front end portion of the cutting apparatus 2.

The cutting apparatus 2 further includes a wafer handling unit 12 for taking the wafer W out of the cassette 10 before cutting or returning the wafer W into the cassette 10 after cutting, a first transfer unit 14 for transferring the wafer W to the chuck table 4 after the wafer W is taken out by the wafer handling unit 12, and a second transfer unit 16 for transferring the wafer W to a spinner cleaning unit 18 after the wafer W held on the chuck table 4 is cut by the cutting blade 8 as being supplied with a cutting fluid (process fluid). After the wafer W is subjected to spin cleaning and spin drying in the spin cleaning unit 18, the wafer W is returned to the cassette 10 by the first transfer unit 14 and the wafer handling unit 12.

A pure water generating apparatus 20 is provided adjacent to the cutting apparatus 2. The pure water generating apparatus 20 functions to purify a cutting water containing cutting dust as a waste fluid discharged from the cutting apparatus 2, thereby generating a pure water. A process fluid supplying apparatus 22 is connected to the cutting apparatus 2 and the pure water generating apparatus 20. The process fluid supplying apparatus 22 functions to add a surface active agent to the pure water, thereby generating a process fluid (cutting fluid) containing the surface active agent at a predetermined concentration, and to supply this process fluid to the cutting apparatus 2. The waste fluid from the cutting apparatus 2 is purified by the pure water generating apparatus 20 to obtain the pure water as mentioned above. This pure water generated by the pure water generating apparatus 20 is mixed with a pure water supplied from a pure water source 24 through an electromagnetic valve 26. The resultant pure water is then introduced into the process fluid supplying apparatus 22.

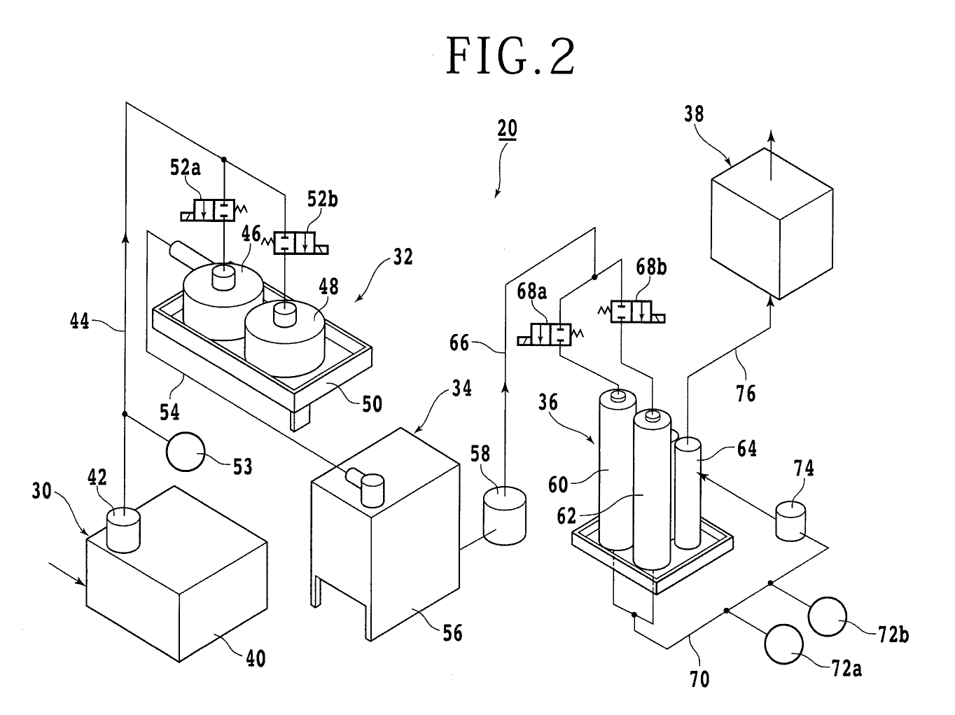

The configuration of the pure water generating apparatus 20 will now be described with reference to FIG. 2. The pure water generating apparatus 20 includes a waste fluid storing unit 30, waste fluid filtering unit 32, fresh water storing unit 34, pure water generating unit 36, pure water temperature adjusting unit 38, and control means (not shown). The waste fluid storing unit 30 functions to store a waste fluid discharged from the cutting apparatus 2. The waste fluid storing unit 30 includes a waste fluid tank 40 for storing the waste fluid from the cutting apparatus 2 and a waste fluid pump 42 for sending out the waste fluid from the waste fluid tank 40.

The waste fluid filtering unit 32 functions to remove cutting dust from the waste fluid sent from the waste fluid storing unit 30, thereby generating a fresh water. The waste fluid filtering unit 32 includes a first filter 46 for filtering the waste fluid sent from the waste fluid storing unit 30 through a pipe 44, a second filter 48 for similarly filtering the waste fluid sent through the pipe 44, and a fresh water pan 50 for detachably accommodating the first filter 46 and the second filter 48. The pipe 44 for connecting the waste fluid pump 42 to the first and second filters 46 and 48 is provided with electromagnetic on-off valves 52a and 52b.

When the electromagnetic on-off valves 52a and 52b are opened, the waste fluid is introduced into the first and second filters 46 and 48, respectively. Further, the pipe 44 is provided with pressure detecting means 53 for detecting the pressure of the waste fluid. Thusly, the first and second filters 46 and 48 function to filter the waste fluid introduced through the pipe 44, thereby removing the cutting dust included in the waste fluid to generate the fresh water. The fresh water thus obtained by the first and second filters 46 and 48 is received by the fresh water pan 50. The fresh water is next sent from the fresh water pan 50 through a pipe 54 such as a flexible hose to the fresh water storing unit 34.

The fresh water storing unit 34 includes a fresh water tank 56 for storing the fresh water sent from the waste fluid filtering unit 32 and a fresh water pump 58 for sending out the fresh water from the fresh water tank 56. The pure water generating unit 36 functions to purify the fresh water sent from the fresh water storing unit 34, thereby generating a pure water. The pure water generating unit 36 includes first ion exchanging means 60, second ion exchanging means 62, a pure water pump 74, and a micro filter 64. The fresh water pump 58 is connected through a pipe 66 to the first and second ion exchanging means 60 and 62, wherein the pipe 66 is provided with electromagnetic on-off valves 68a and 68b. When the electromagnetic on-off valves 68a and 68b are opened, the fresh water is sent from the fresh water tank 56 through the pipe 66 to the first and second ion exchanging means 60 and 62, respectively.

The first and second ion exchanging means 60 and 62 function to perform ion exchange, thereby purifying the fresh water to generate the pure water. The pure water generated by the first and second ion exchanging means 60 and 62 is sent at a predetermined pressure through a pipe 70 to the micro filter 64 by operating the pure water pump 74. The pipe 70 is provided with pressure detecting means 72a and 72b for detecting the pressure of the pure water sent from the first and second ion exchanging means 60 and 62. The micro filter 64 functions to remove a minute substance such as resin dust due to an ion exchange resin constituting the first and second ion exchanging means 60 and 62. Accordingly, the pure water sent from the first and second ion exchanging means 60 and 62 is further purified by the micro filter 64 to obtain a final pure water. The pure water temperature adjusting unit 38 functions to adjust the temperature of this final pure water to a predetermined temperature and then supply this final pure water to the process fluid supplying apparatus 22.

The control means (not shown) included in the pure water generating apparatus 20 functions to control the above components of the pure water generating apparatus 20 in generating the pure water from the waste fluid discharged from the cutting apparatus 2. More specifically, the control means controls the electromagnetic on-off valves 52a, 52b, 68a, and 68b, the fresh water pump 58, and the pure water pump 74 according to the detection signals from the pressure detecting means 53, 72a, and 72b. After the waste fluid is stored into the waste fluid storing unit 30, the waste fluid is filtered by the waste fluid filtering unit 32 under the control by the control means to obtain the fresh water. After the fresh water is stored into the fresh water storing unit 34, the fresh water is subjected to the ion exchange and the microfiltration by the pure water generating unit 36 under the control by the control means to obtain the pure water. Thereafter, the pure water is further processed by the pure water temperature adjusting unit 38 under the control by the control means.

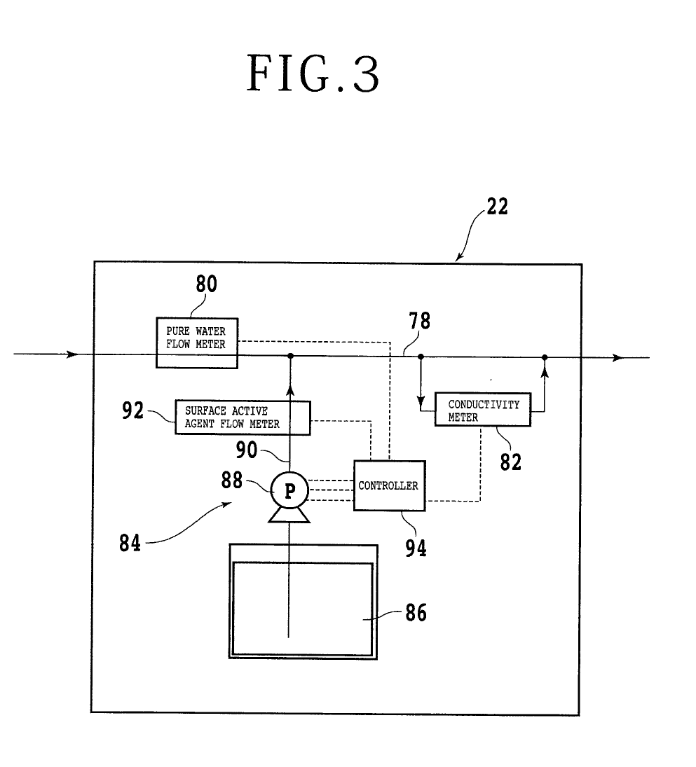

The configuration and operation of the process fluid supplying apparatus 22 will now be described with reference to FIG. 3. The process fluid supplying apparatus 22 includes a pure water passage 78 for providing the flow of the mixture of the pure water generated by the pure water generating apparatus 20 and the pure water supplied from the pure water source 24. The pure water passage 78 is provided with a pure water flow meter 80 for measuring the flow rate of the pure water flowing in the pure water passage 78. The process fluid supplying apparatus 22 further includes surface active agent supplying means 84 for supplying a predetermined amount of surface active agent to the pure water flowing in the pure water passage 78. The surface active agent supplying means 84 includes a tank 86 for storing a surface active agent and a pump 88 for raising the surface active agent from the tank 86. The surface active agent raised by the pump 88 is supplied through a supply passage 90 to the pure water flowing in the pure water passage 78.

Preferably, the surface active agent includes an alkali salt of polycarboxylic acid. Specifically, examples of the alkali salt of polycarboxylic acid include an alkali salt of a homopolymer or copolymer of unsaturated fatty acid such as an alkali salt of a homopolymer or copolymer of acrylic acid or methacrylic acid and an alkali salt of a homopolymer or copolymer of maleic acid.

More specifically, examples of the alkali salt of polycarboxylic acid include an alkali salt of polyacrylic acid, an alkali salt of polymethacrylic acid, an alkali salt of polyalkenyl succinic acid, an alkali salt of a copolymer of a-olefin such as isobutylene and maleic anhydride or acrylic acid, an alkali salt of a copolymer of acrylic acid or methacrylic acid and maleic acid, an alkali salt of a copolymer of styrene sulfonic acid and acrylic acid or methacrylic acid, and an alkali salt of a copolymer of acrylic acid and acrylamide. Of these examples, an alkali salt of polyacrylic acid, particularly, a Na salt or ammonium salt of polyacrylic acid is more preferable.

The pump 88 is provided by a diaphragm pump, and it is adapted to supply a small amount of fluid. The pump 88 can supply a minute amount of surface active agent over plural times in a predetermined period of time. The supply passage 90 is provided with a surface active agent flow meter 92. The surface active agent supplying means 84 functions to supply a predetermined amount of surface active agent to the pure water flowing in the pure water passage 78 so that the concentration of the surface active agent with respect to the flow rate of the pure water becomes a predetermined concentration. The surface active agent supplied by the surface active agent supplying means 84 is mixed with the pure water flowing in the pure water passage 78 in the condition of a turbulent flow.

The pure water flow meter 80 provided in the pure water passage 78 and the surface active agent flow meter 92 provided in the supply passage 90 are connected to control means (controller) 94 included in the process fluid supplying apparatus 22. The control means 94 functions to drive the pump 88 so that the concentration of the surface active agent in the pure water becomes a predetermined concentration. That is, the control means 94 controls the pump 88 so that the flow rate of the surface active agent measured by the surface active agent flow meter 92 becomes a predetermined amount with respect to the flow rate of the pure water measured by the pure water flow meter 80. Preferably, the control means 94 drives the pump 88 so as to supply a predetermined amount of surface active agent separately over plural times.

For example, the predetermined concentration of the surface active agent is obtained by adding the surface active agent flowing at a flow rate of 0.25 cc/minute to the pure water flowing at a flow rate of 2.5 L/minute in the pure water passage 78. In this case, the predetermined concentration of the surface active agent is a concentration corresponding to a 10000-fold dilution factor, and this concentration is equal to 0.01%. The pure water passage 78 is further provided with a conductivity meter 82 for measuring the conductivity (electrical conductivity) of the process fluid flowing in the pure water passage 78 after adding the surface active agent to the pure water. That is, the conductivity meter 82 is located in a downstream portion of the pure water passage 78 downstream of a joining point where the supply passage 90 joins with the pure water passage 78. The conductivity meter 82 is also connected to the control means 94.

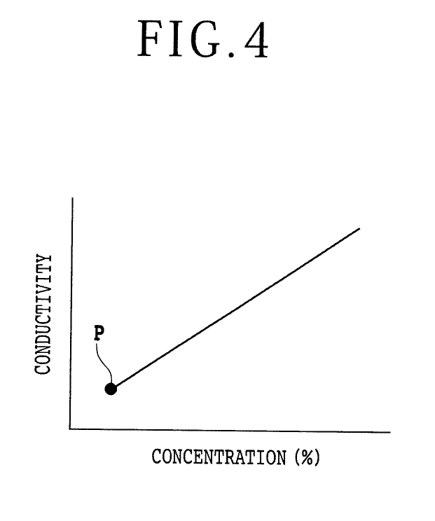

The control means 94 has a determining portion for determining that the surface active agent has been added to the pure water when the conductivity measured by the conductivity meter 82 is greater than a threshold value. As shown in FIG. 4, there is a linear relation between the conductivity of the process fluid and the concentration of the surface active agent. Accordingly, by measuring the conductivity of the process fluid, the concentration of the surface active agent in the process fluid can be determined.

In FIG. 4, reference symbol P denotes the conductivity of the pure water. As apparent from FIG. 4, the conductivity of the process fluid obtained by adding the surface active agent to the pure water increases with an increase in concentration of the surface active agent. Accordingly, the concentration of the surface active agent in the process fluid can be determined by measuring the conductivity of the process fluid with the conductivity meter 82. For example, in the case that the predetermined concentration of the surface active agent in the process fluid is less than or equal to 0.1%, the conductivity of the process fluid is 1 to 70 μS/cm. Accordingly, the concentration of the surface active agent in the process fluid can be maintained in a preferable predetermined range by measuring the conductivity of the process fluid with the conductivity meter 82.

While the tank 86 containing the surface active agent is provided inside the process fluid supplying apparatus 22 in this preferred embodiment, the tank 86 may be provided outside the process fluid supplying apparatus 22. Further, ultraviolet light applying means may be provided between the fresh water tank 56 and the ion exchanging means 60 and 62 to sterilize the fresh water and remove organic matter.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A process fluid circulation type processing system comprising:
a processing apparatus for processing a workpiece held on a chuck table as supplying a process fluid to said workpiece;
a process fluid supplying apparatus for adding a surface active agent to a pure water to thereby produce said process fluid at a predetermined concentration and then supplying said process fluid to said processing apparatus; and
a pure water generating apparatus for removing processing dust and any impurities including said surface active agent from a waste fluid discharged from said processing apparatus to thereby generate said pure water and then supplying said pure water generated above to said process fluid supplying apparatus;
said process fluid supplying apparatus including a pure water passage for providing the flow of said pure water, a pure water flow meter for measuring the flow rate of said pure water flowing in said pure water passage, and surface active agent supplying means for supplying said surface active agent to said pure water flowing in said pure water passage at a position downstream of said pure water flow meter;
said surface active agent supplying means supplying a predetermined amount of said surface active agent so that the concentration of said surface active agent with respect to the flow rate of said pure water becomes a predetermined concentration;
said surface active agent supplied by said surface active agent supplying means being mixed with said pure water flowing in said pure water passage in the condition of a turbulent flow.

2. The process fluid circulation type processing system according to claim 1,
wherein said surface active agent supplying means supplies said predetermined amount of said surface active agent separately over plural times.

3. The process fluid circulation type processing system according to claim 1,
wherein said process fluid supplying apparatus further includes
a conductivity meter for measuring the conductivity of said process fluid flowing in said pure water passage after adding said surface active agent to said pure water, and
control means connected to said conductivity meter for determining that said surface active agent has been added to said pure water when the conductivity measured by said conductivity meter is greater than a threshold value.

4. The process fluid circulation type processing system according to claim 1,
wherein said surface active agent supplying means includes a surface active agent source, a supply passage for connecting said surface active agent source to said pure water passage, a pump provided in said supply passage for feeding said surface active agent to said pure water passage, and a surface active agent flow meter provided in said supply passage for measuring the flow rate of said surface active agent flowing in said supply passage,
said pump being controlled so that the flow rate of said surface active agent measured by said surface active agent flow meter becomes said predetermined amount with respect to the flow rate of said pure water measured by said pure water flow meter.

5. The process fluid circulation type processing system according to claim 1,
wherein said surface active agent includes an alkali salt of polycarboxylic acid.
